(19) United States
(12) Patent Application Publication
(10) Pub. No.: US 2007/0234945 A1
(43) Pub. Date: Oct. 11, 2007

(54) Photovoltaic floatation device

(76) Inventors: Bruce M. Khouri, Glendale, CA (US); Kevin D. Tabor, Lausanne (CH); Randall E. Jurisch, La Crescenta, CA (US); Joel Davidson, Culver City, CA (US); Roke A. Castro, Signal Hill, CA (US)

Correspondence Address: CHRISTIE, PARKER & HALE, LLP, PO BOX 7068, PASADENA, CA, 91109-7068, US

(21) Appl. No.: 11/606,697

(22) Filed: Nov. 28, 2006

Related U.S. Application Data
(60) Provisional application No. 60/740,559, filed on Nov. 28, 2005.

(51) Int. Cl. B63B 35/00; H01L 31/042

(52) U.S. Cl. 114/266; 136/251

(57) ABSTRACT

A device and system for generating electricity with a photovoltaic floatation device is provided. The device comprises one or more photovoltaic cells, which are attached to a panel that is removably attached to a floatation element. The device allows users to utilize the surface areas of water for placement of photovoltaic cells. Multiple devices can be mechanically connected to allow for the formation of one or more photovoltaic floatation device grids. The system comprises one or more photovoltaic floatation devices that are anchored to a particular area in a body of water and are electrically connected to one or more inverters.

### CROSS-REFERENCE TO RELATED APPLICATION(S)

This Application claims the benefit of U.S. Provisional Application Ser. No. 60/740,559 filed on Nov. 28, 2005, which is incorporated herein by reference.

### FIELD OF THE INVENTION

The present invention relates to a floatation device with a photovoltaic panel having photovoltaic modules. The device is able to float on water and generate electricity.

### DESCRIPTION OF RELATED ART

Solar energy has received increasing attention as an alternative renewable, non-polluting energy source to produce electricity as a substitute to other non-renewable energy resources, such as coal or oil that also generate pollution. Given the increase in the price of non-renewable resources such as oil, it has become even more advantageous for companies and individuals to look to solar energy as a cost saving alternative. However, one drawback of solar energy is that the photovoltaic cells used to generate the electricity require a large amount of space so that a large surface area of cells can be exposed to sunlight.

This drawback is especially evident in areas where land is scarce and is needed for other applications. In these areas, land is far too valuable to commit to energy production. Thus, users in such areas are forced to purchase electricity from a power company or utilize expensive alternatives such as generators.

However, in many areas bodies of water are plentiful. In much of these areas, individuals as well as companies own land containing bodies of water or bordering bodies of water. Much of the time, these bodies of water go untouched as the activities of the individual or company are confined to the land. Hence, it would be advantageous to utilize the vast amount of surface space of bodies of water for the placement of photovoltaic cells.

One system disclosed in Japanese Patent Publication No. S57-17181 combines photovoltaic cells with a floating apparatus so that the cells can be floated on water. For example, the known system contains a floating body made up of a plurality of connected floating elements. The floating body has a plurality of solar cells attached thereon. The solar cells are electrically connected to an external current collector.

However, the known art easily collects dirt and water on the top surface. Furthermore, the known art discloses a device where the user must dispose of the entire device if either the floatation element or the affixed solar cells become unusable. Moreover, in the known art, electrical wires that carry current between photovoltaic cells are completely exposed to the outside elements and can be easily damaged from strong winds and rocky tides.

Therefore, a need exists for a photovoltaic floatation device that is designed to withstand the elements present in a body of water and allow for easy, cost effective maintenance.

### SUMMARY

In one embodiment, a photovoltaic floatation device comprises a photovoltaic laminate panel. The device further comprises a floatation element, wherein the photovoltaic laminate panel is removably attached to the floatation element.

In another embodiment, a system for generating electricity comprises one or more photovoltaic floatation devices that are mechanically connected with one or more fasteners. The system further comprises one or more photovoltaic floatation devices electrically connected to one or more combiner boxes. The one or more combiner boxes are electrically connected to one or more combiner-combiner boxes. The system further comprises one or more inverters, wherein the one or more combiner-combiner boxes are electrically connected to the one or more inverters.

### BRIEF DESCRIPTION OF THE DRAWINGS

Referring now to the drawings in which like reference numbers represent corresponding parts throughout:

FIG. 1 is a perspective view of one embodiment of the photovoltaic floatation device.

FIG. 2 is an end view of a cross section of the embodiment shown in FIG. 1.

FIG. 3 is a top view of a cross section of the embodiment shown in FIG. 1.

FIG. 4 is a cross section view of a PV laminate panel.

FIG. 5 illustrates the interface of the PV laminate panel and the floatation element.

FIG. 6 is a top view of two devices of the embodiment of FIG. 1 connected.

FIG. 7 illustrates a carabiner connector locking a pair of grommet tabs on adjacent floatation elements.

FIG. 8 is a perspective view of an alternative of a photovoltaic floatation device with a foam insert inserted into the floatation element.

FIG. 9 is a perspective view of another embodiment of a photovoltaic floatation device with individual tubular air bladders within the floatation element.

FIG. 10 is a top view of a cross section of the embodiment of FIG. 9.

FIG. 11 is a perspective view of another embodiment with two stabilizing pontoons attached to the side of a main body pontoon.

FIG. 12 is a top view of two of the devices depicted in FIG. 11 connected with a walkway placed over the connection area.

FIG. 13 is a top view of another embodiment of two main body pontoons connected at each of their sides with one stabilizing pontoon, equal in length to the connected main body pontoons.

FIG. 14 is a top view of one embodiment of a photovoltaic floatation device with a floating scaffold attached thereto.

FIG. 15 is a schematic view of one embodiment of a photovoltaic floatation device system of the present invention fully installed and deployed in water.

FIG. 16 illustrates a plan view of an array of connected photovoltaic floatation devices.

FIG. 17 is a perspective view of one embodiment of a photovoltaic floatation device with a catamaran style floatation element.

### DETAILED DESCRIPTION

The present invention is directed to a photovoltaic floatation device, which comprises at least one floatation element, capable of floating on water, and at least one photovoltaic module attached thereto. Having generally described some of the features of the present invention, in the following description, reference is made to the accompanying drawings, which form a part hereof and that show by way of illustration specific embodiments in which the invention may be practiced. It is to be understood that other embodiments may be utilized as structural changes may be made without departing from the scope of the present invention.

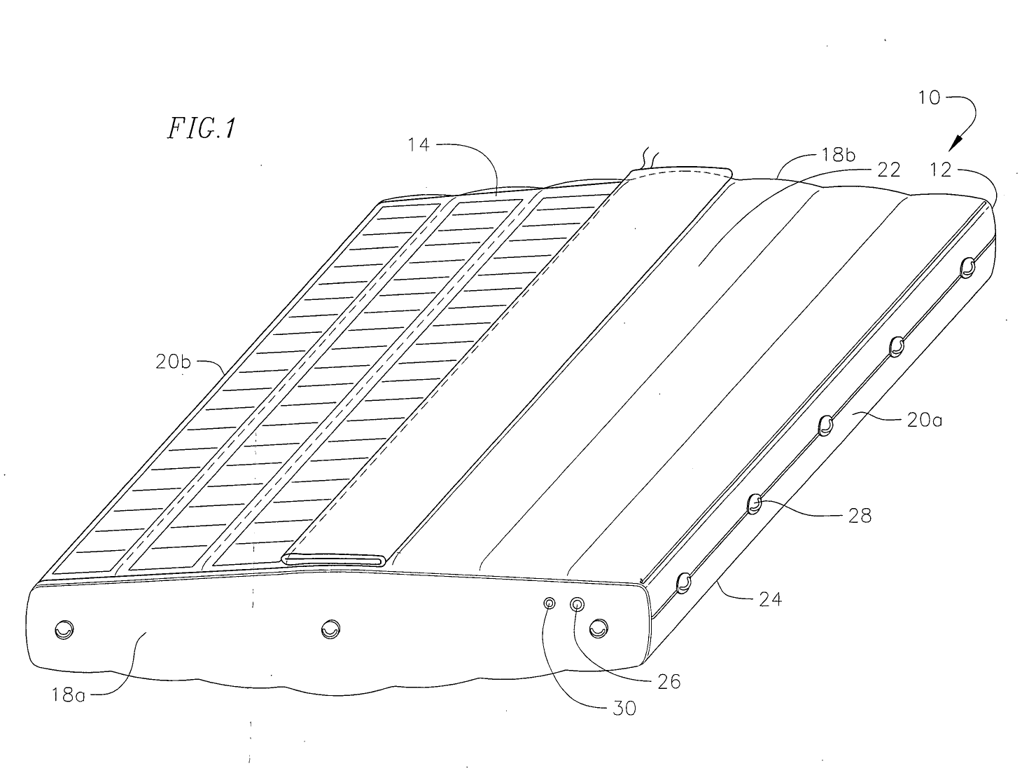

Referring to FIG. 1, one embodiment of the present invention provides a photovoltaic floatation device 10, which comprises a single floatation element 12 with a photovoltaic (PV) laminate panel 14 attached thereon. The floatation element 12 is inflatable and can be comprised for example of material such as PVC, TPO or Hypalon. However one skilled in the art would appreciate that the floatation element 12 can comprise any durable material that has a high impermeability to air and water.

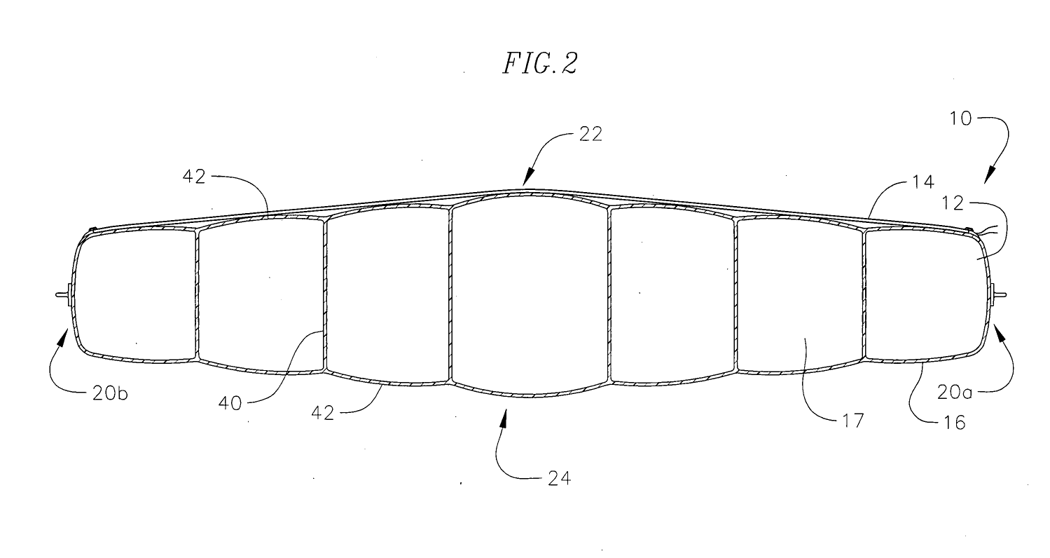

Referring to FIGS. 1 and 2, the floatation element 12 comprises a skin 16 forming a cavity 17 therein, which when inflated forms a generally rectangular shape with two ends 18a and 18b, two sides 20a and 20b, a top 22 and a bottom 24. Attached, to the skin 16 of the floatation element 12, for example with a heat weld, is an inflation device 26, which allows for the inflation and deflation of the floatation element 12. Attached along the outer perimeter of the floatation element 12, for example with a heat weld, are grommet tabs 28, which will be described in more detail later in the application.

Furthermore, an overpressure valve 30 is attached to the skin 16 of the floatation element 12 at a height that is above the waterline of the device 10, and promotes the pressure equalization in the floatation element 12. The proper air pressure is maintained within the floatation element 12 by an auxiliary pressurizing pump (not shown).

The top 22 of the floatation element 12 is sloped, and can have any slope that promotes the shedding of water and dirt from the PV laminate panel 14. In one embodiment the slope is about 5 degrees or less so that the loss of solar radiation exposure is minimized. Thus, when the PV laminate panel 14 is attached to the top 22 of the floatation element 12, the flexible nature of the panel 14 adopts the sloped shape of the top 22 of floatation element 12. This prevents water and dirt from collecting on the top of the PV laminate panel 14.

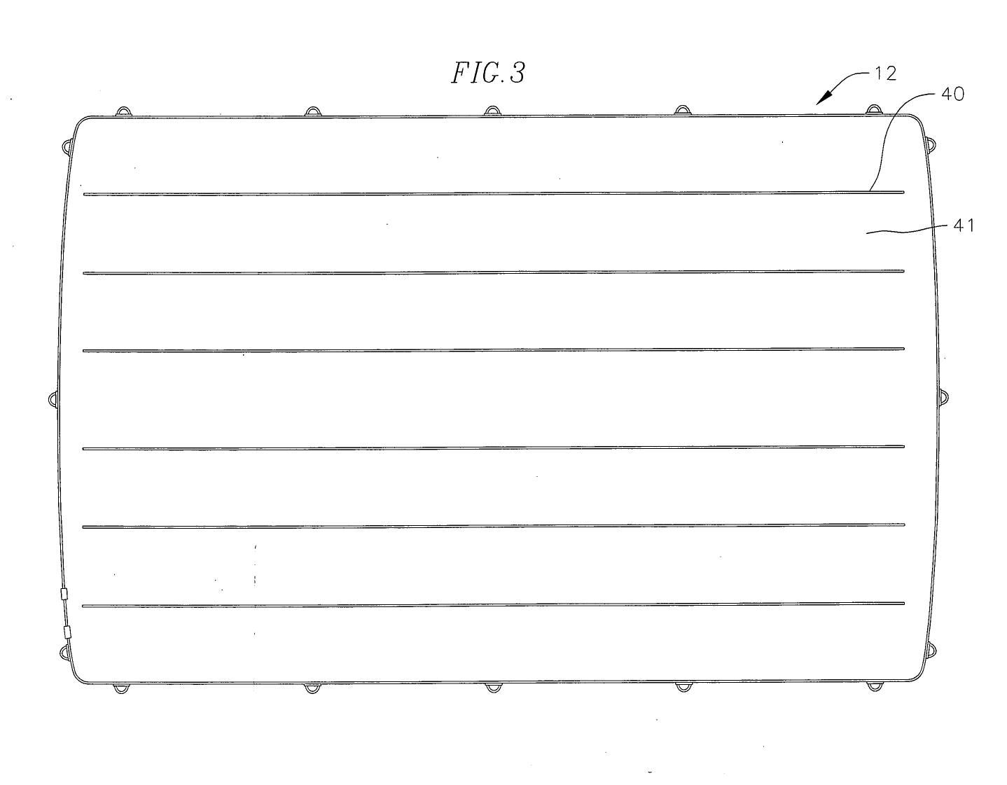

Referring to FIGS. 2 and 3, the floatation element 12 comprises a plurality of internal support walls 40 attached to the top 22 and bottom 24 of the floatation element 12, for example by heat welding. The internal support walls 40, which act as a support structure for the floatation element 12, form the top 22 of the floatation element 12 into a plurality of arc shaped sections 42 of skin 16. The internal support walls 40 extend longitudinally along, and parallel to, sides 20a and 20b of the floatation element 12.

However, the internal support walls 40 do not extend entirely to ends 18a and 18b. Therefore, the air space 41 between the internal support walls 40 remains in fluid communication at all times. The height of the internal support walls 40 determines the slope of the top 22 of the floatation device 10 when the device is fully inflated.

Removably attached to the floatation element 12 is the PV laminate panel 14 that has one or more photovoltaic modules affixed thereon. Examples of a flexible panel with one or more photovoltaic modules affixed thereon are described in U.S. Pub. Nos. 2004/0144043 and 2005/0072456, incorporated by reference herein. The flexible panel can be made of polymers such as PVC or any other suitable flexible materials, such as fabric, nylon, canvass, etc.

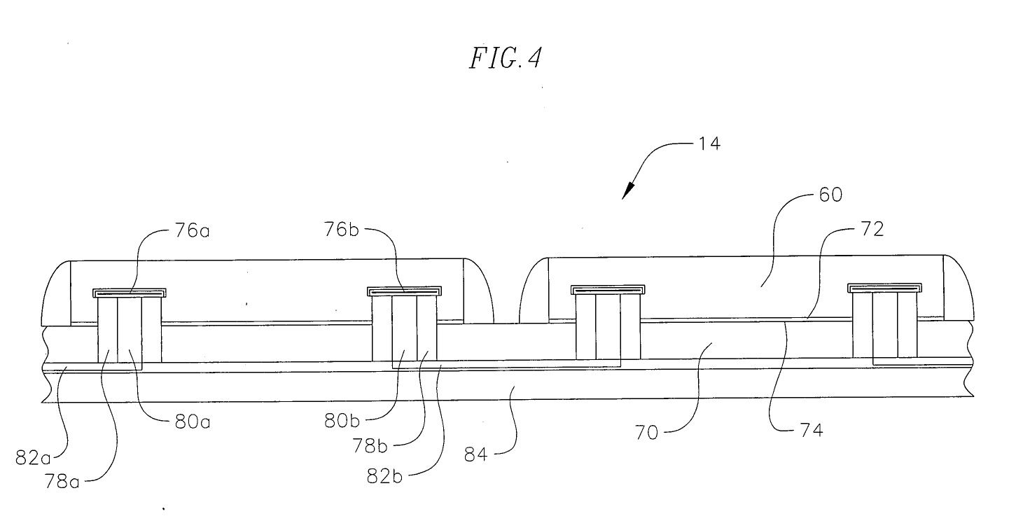

Referring to FIG. 4, the incorporated publications disclose a combination roofing panel and solar module that includes a flexible membrane 70 and a plurality of elongated solar or photovoltaic modules 60 arranged side-by-side, end-to-end, and/or otherwise adjacent to each other. The photovoltaic modules 60 are attached with an adhesive 72 to a flexible membrane 70. The photovoltaic modules 60 are adhered to top surface 74 of the flexible membrane 70. An exemplary photovoltaic module 60 that can be used is a UNI-SOLAR® PVL module, available from United Solar Ovonic, 3800 Lapeer Road, Auburn Hills, Mich. An exemplary flexible membrane 70 that can be used is a single-ply membrane, e.g., an EnergySmart® S327 Roof Membrane, available from Sarnafil, Inc. Roofing and Waterproofing Systems, 100 Dan Road, Canton Mass. However, one skilled in the art would appreciate that other types of photovoltaic modules 60 could be used such as crystalline modules 60.

The photovoltaic modules 60 include negative and positive internal soldering pads 76a(−) and 76b(+), respectively. Apertures 78a and 78b are formed through the flexible membrane 70, adhesive 72 and a lower portion of the photovoltaic module 60, to access the internal soldering pads 76a and 76b. Electrical connections 80a and 80b are formed within the apertures 78a and 78b, between the internal module soldering pads 76a and 76b and the intermodule soldering connection leads 82a and 82b.

As a result, the internal module negative electrode soldering pads 76a, electrical connection 80a, and wire connection lead 82a provide an electrical circuit. The internal positive electrode soldering pads 76b, electrical connection 80b, and wire connection lead 82b provide an electrical circuit connected in series to the adjacent negative electrode soldering pads 76a. If necessary, one or more insulative layers 84 can be adhered to the bottom surface of the flexible membrane 70 and over the wire connection leads 82a and 82b. The negative and positive wire connection leads 82a and 82b are then ran out of the flexible membrane and a waterproof connecter (not shown) is attached at their ends.

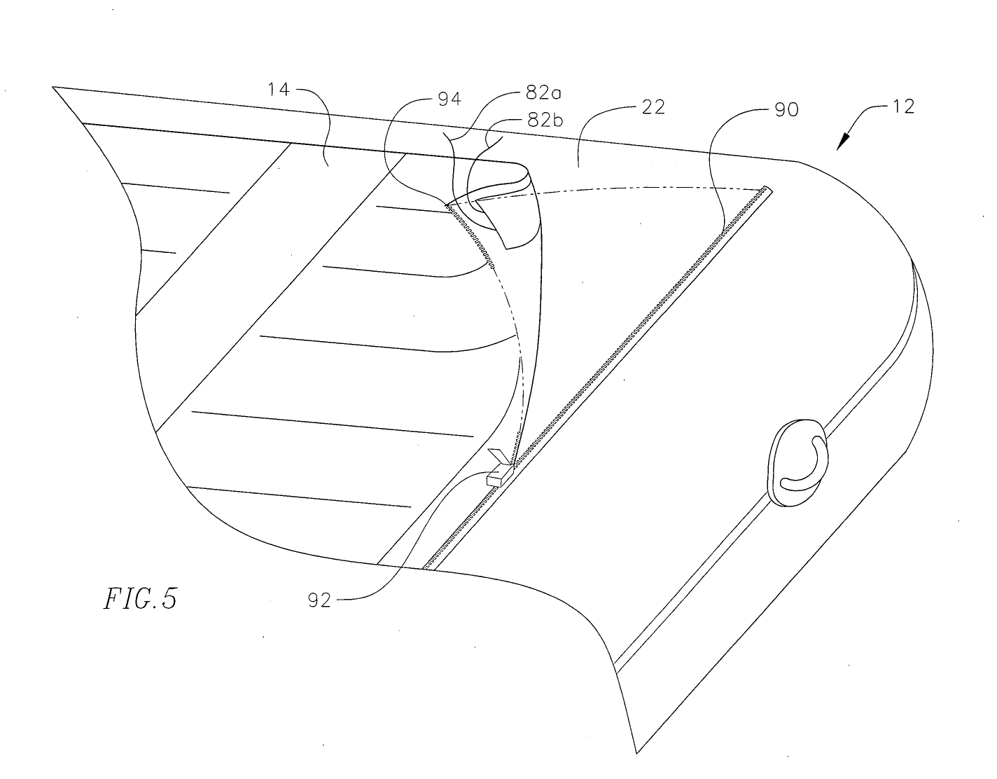

The PV laminate panel 14 is removably attached to the floatation element 12 with fasteners such as zippers, buttons, snaps, kedering, hook and loop fasteners, laces, twist-locks, magnets or any other fasteners capable of securely and removably attaching the PV laminate panel 14 to the floatation element 12. For example, referring to FIG. 5, heat welded onto the top 22 of the floatation element 12 are a group of teeth 90, with a slider 92 attached therein, which are part of a zipper mechanism. Attached with a heat weld to the outer edge of the PV laminate panel 14 are a second group of teeth 94. In order to attach the panel 14 to the floatation element the slider 92 is used to engage, and connect, both groups of teeth 90 and 94. Furthermore, the wire connection leads 82a and 82b can extend out from the bottom of the PV laminate panel 14 at the interface of a corner of the floatation element 12 and PV laminate panel 14.

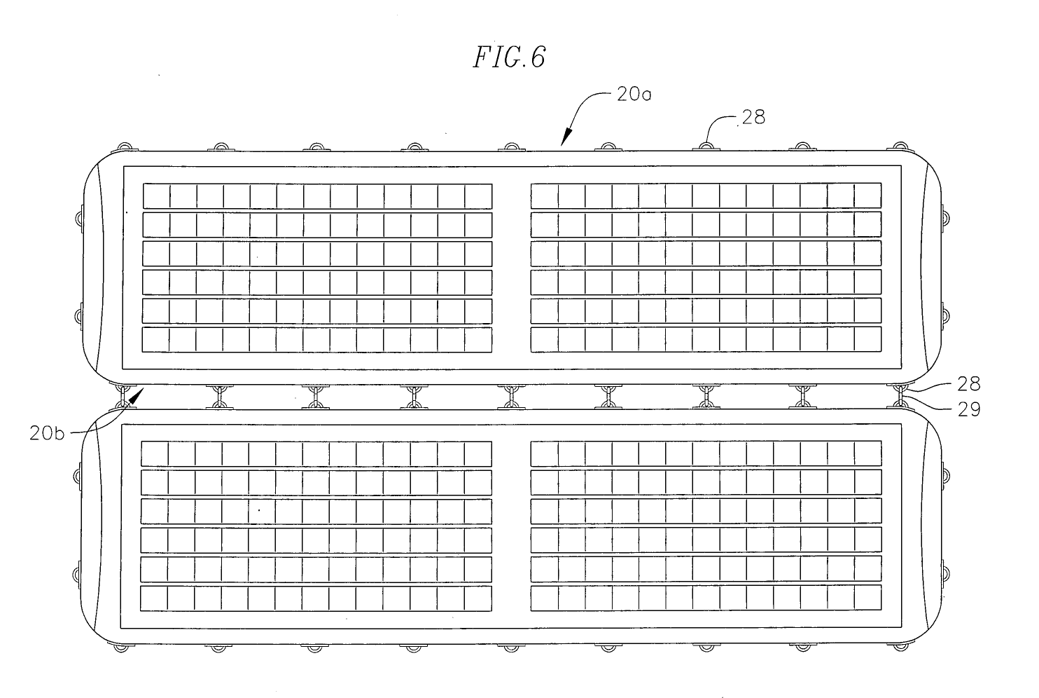

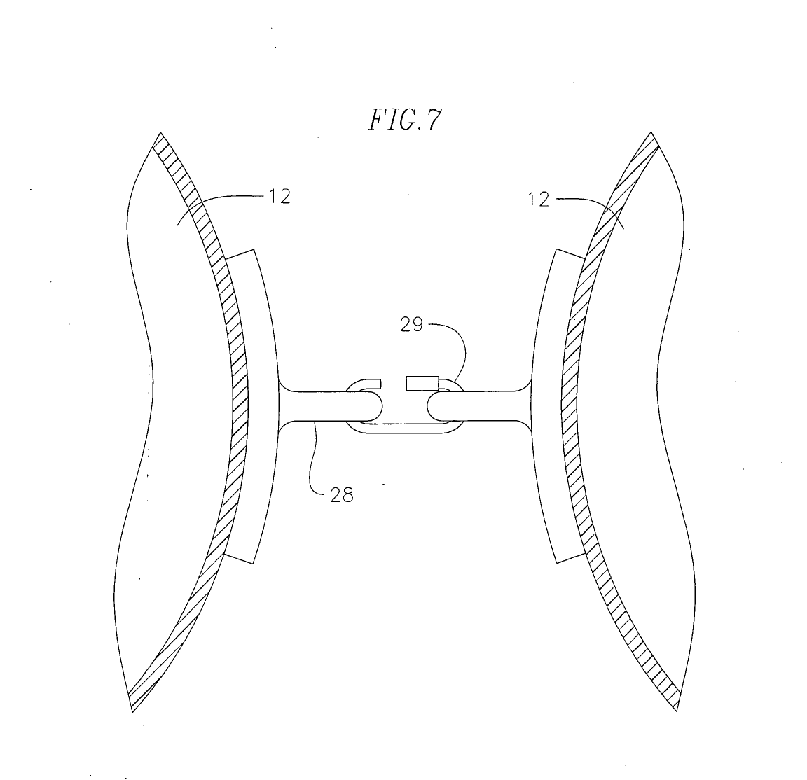

Referring to FIG. 6, in another embodiment, grommet tabs 28 are attached along sides 20a and 20b of the floatation element 12, for example by a heat weld. Referring also to FIG. 7, carabiner connectors 29 are used to lock together grommet tabs 28 attached along the edge of the floatation elements 12 of the two devices 10. Alternatively, one or more hook-and-loop fasteners, attached along the edge of the two devices with a heat weld, may be used to connect multiple devices.

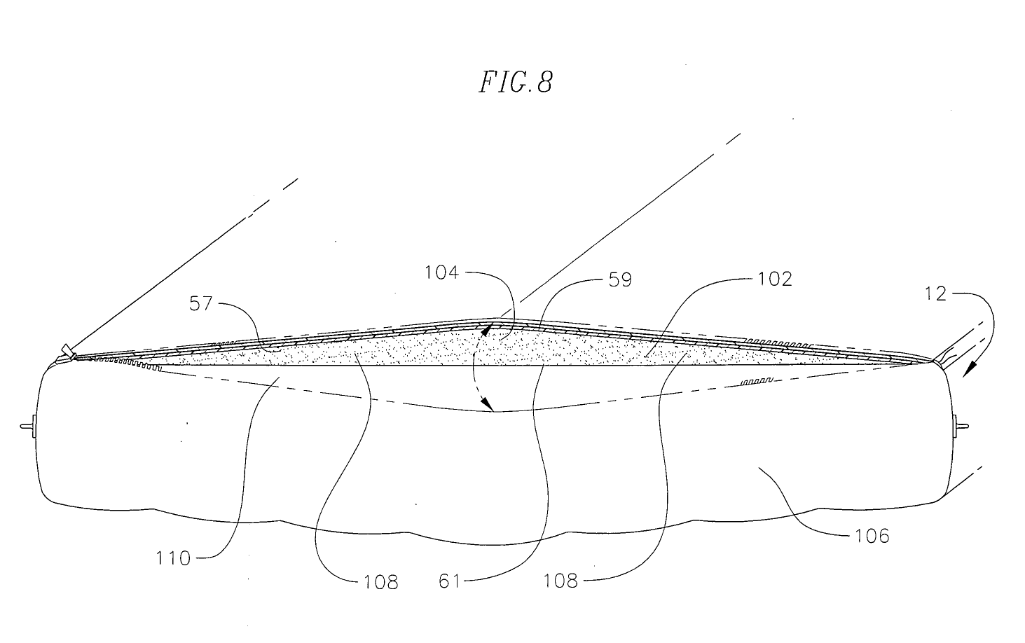

Referring to FIG. 8, in another embodiment a top portion 57 of the floatation element 12 comprises a foam insert 102 that is capable of floating on water. The foam insert 102 is comprised of Styrofoam, polyisocyanurate, or alternatively, a 2-part catalytic foam. The top portion 57 is attached to a bottom portion 106, for example with a heat weld, at an intermediate layer 61 of skin 16. The top portion 57 of the floatation element 12 is defined by a top layer 59 of skin 16 and the intermediate layer 61 of skin 16. In one embodiment, a top portion 104 of the foam insert 102 has a sloped pitch of 5 degrees or less. The bottom portion 106 of the floatation element 12 is inflatable.

The insert 102 can be inserted into, and removed from, the top portion 57 of the floatation element 12 through an opening 108 in the skin 16 of the floatation element 12. The opening 108 is created by a flap 110 of fabric, which for example is sealed and unsealed with a zipper mechanism. Alternatively, the foam insert 102 may be inserted into the top portion 57 during manufacturing and permanently sealed into the skin 16 of the floatation element 12.

In another embodiment, one large floatable foam insert 102 may be placed into the entire floatation element 12. In this embodiment, there are no inflatable air bladders. The foam insert 102 is rigid, and thus maintains its intended shape. Alternatively, a two part polyurethane mixture of float gel, or other floatable material, can be used in place of the foam insert 102.

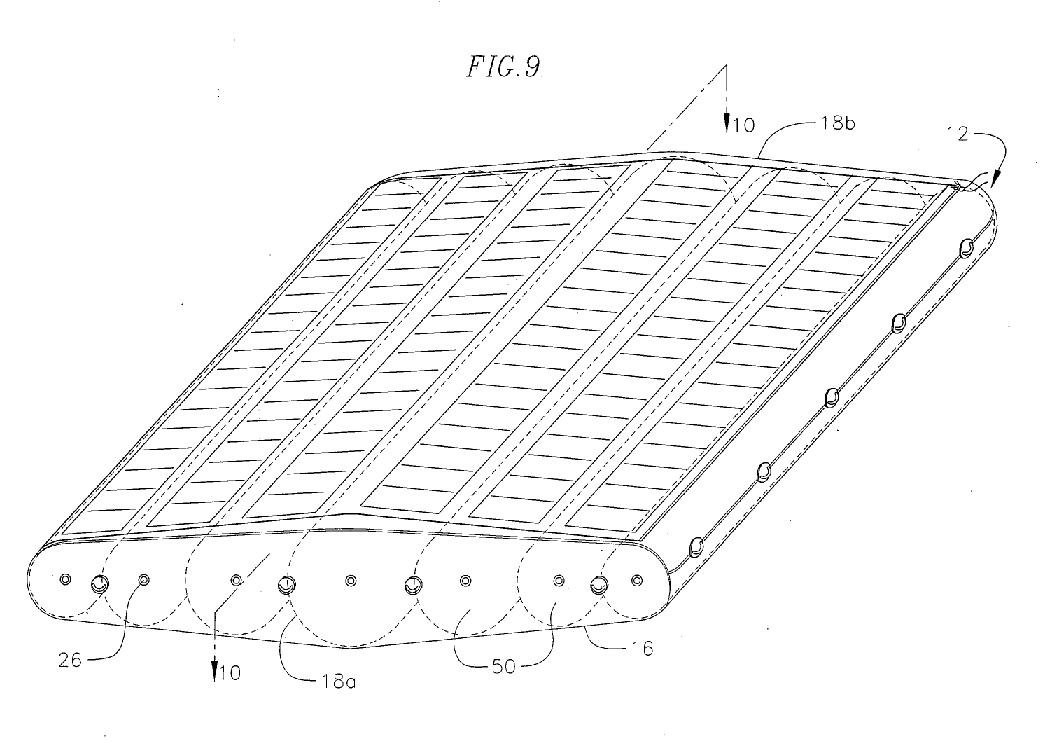

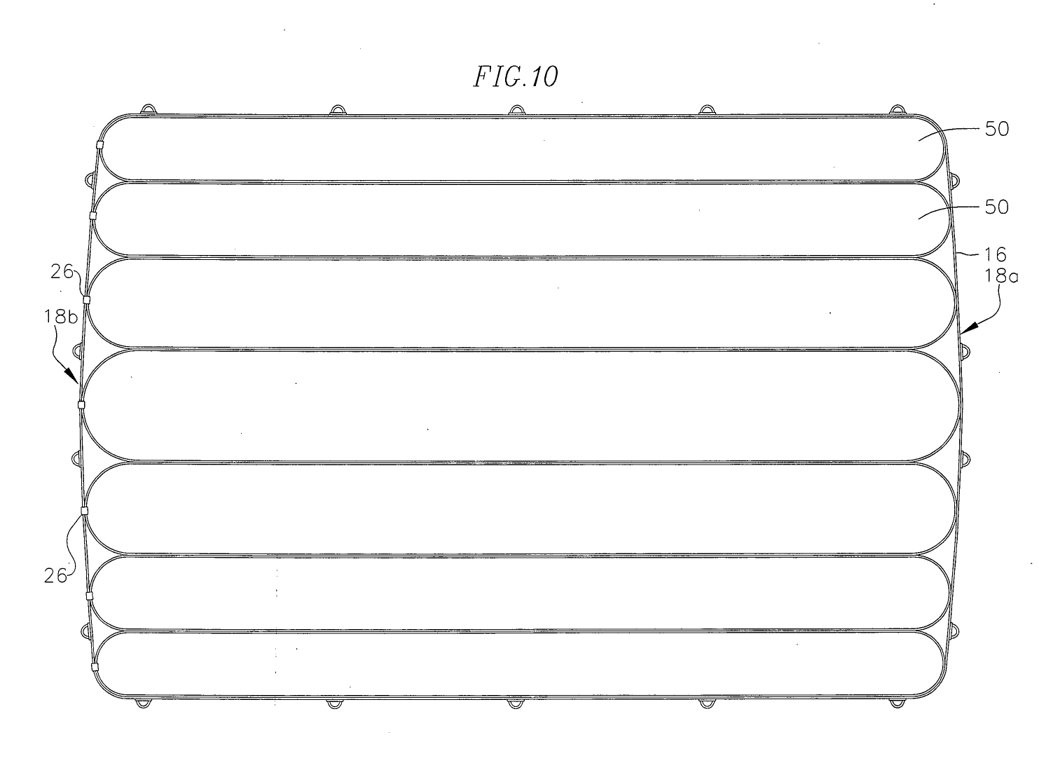

Referring to FIGS. 9 and 10, in another embodiment, the floatation element 12 comprises one or more air bladders 50. The air bladders 50 are generally tubular in shape and can be attached with a heat weld to the inner side of the skin 16 of the floatation element 12.

The one or more air bladders 50 are arranged longitudinally from one end 18a of the floatation element 12 to the opposite end 18b. However, one skilled in the art would appreciate that the air bladders 50 could be arranged in various configurations within the floatation element 12. Furthermore, in one embodiment, the air bladders 50 and skin 16 of the floatation element 12 are made of bullet proof material to prevent vandals from easily deflating the devices 10.

The one or more air bladders 50 are linked to, and in fluid communication with one another so that when one air bladder 50 is inflated, air is dispersed to all the linked air bladders 50. Alternatively, the air bladders 50 may be isolated, and not in fluid communication with one another. In this alternative, each air bladder 50 is inflated independently of the other air bladders 50 so that in the event one air bladder 50 is damaged, the damaged air bladder 50 does not affect the air pressure in the remaining air bladders.

When the air bladders 50 are linked, the floatation element 12 includes one inflation device 26, which extends out from, and can be heat welded to, the skin 16 of the floatation element 12. This allows for simultaneous inflation of all of the linked air bladders. Alternatively, if the air bladders 50 are isolated, each air bladder 50 may have a separate inflation device 26 extending out from the skin 16 of the floatation element 12, allowing the user to supply air to each air bladder 50 individually.

One method of inflating the skin 16 involves connecting an air source to an inflation device 26. The inflation device 26 may comprise a valve, which allows for the free flow of air when engaged by an air compressor. However, one skilled in the art would appreciate that the inflation device 26 can be any passage capable of exposing the inside of the floatation element 12 to an air source and preventing the air from escaping during use of the device 10.

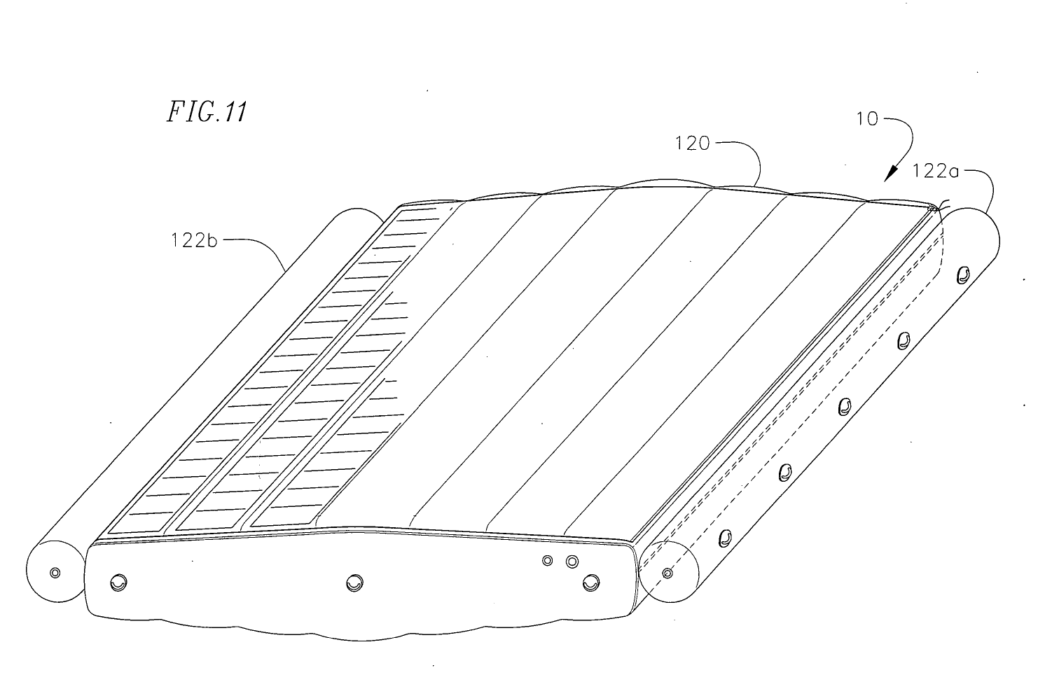

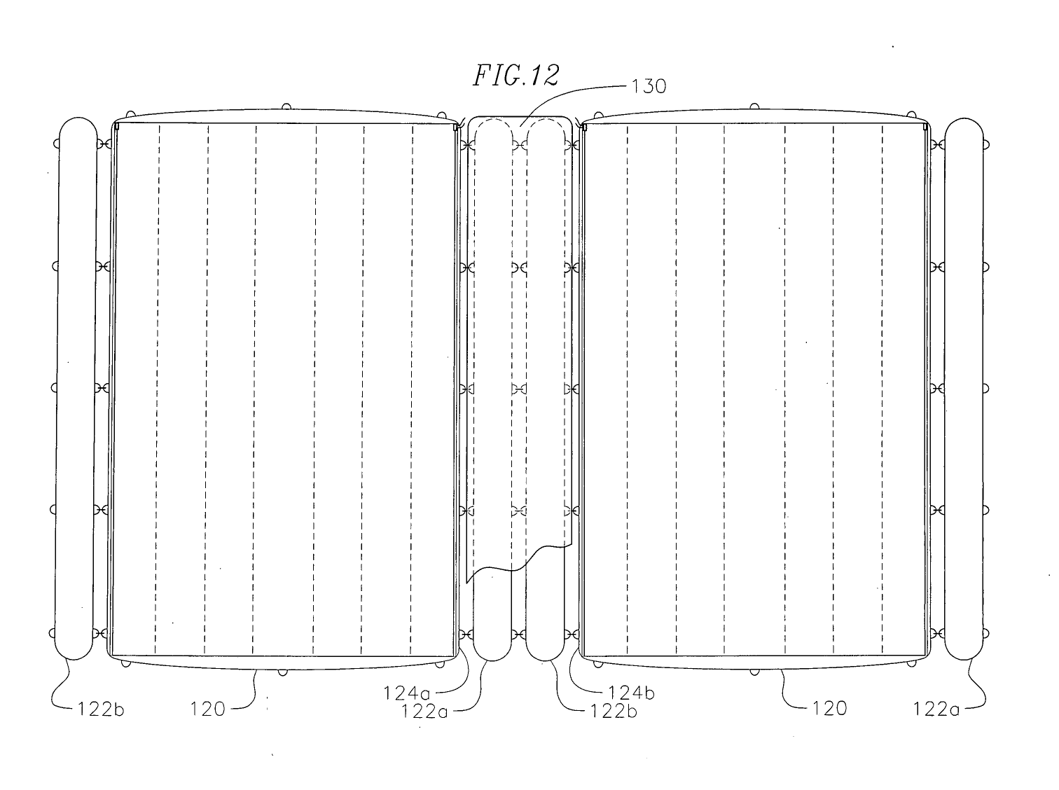

Referring to FIGS. 11 and 12, in another embodiment of the present invention, the floatation element 12 of the photovoltaic floatation device 10 comprises three separate floatation objects 120, 122a and 122b. These floatation objects 120, 122a and 122b comprise a main body pontoon 120 and one or more stabilizing pontoons 122, which are attached to the main body pontoon 120.

Referring to FIG. 12, the one or more stabilizing pontoons 122 are removably attached to the main body pontoon 120. The stabilizing pontoons 122a and 122b can be removably attached to the main body pontoon 120 with carabiner connectors 29 that interlock with grommet tabs 28, which are attached along the sides 124a and 124b of the main body pontoon 120 and the side of the stabilizing pontoon 122. Alternatively, the stabilizing pontoons 122 can be removably attached to the main body pontoon 120 with zippers, kedering, snaps, laces, hook and loop fasteners, magnets or any other type of re-useable fastener that is capable of withstanding the pulling force on the pontoon elements 122 from the current in the body of water. Alternatively, the stabilizing pontoons 122 are permanently connected to the main body pontoon 120 with for example glue or a heat weld.

Both the main body pontoon 120 and the stabilizing pontoons 122 are inflatable. Alternatively, a foam insert 102, or other suitable floatable material, is placed into the main body pontoon 120 and/or the stabilizing pontoons 122.

Furthermore, a walkway 130 can be laid along the area where multiple devices are connected. The walkway 130 can be attached with straps or alternatively may just be laid on top of the devices without any attachment mechanism. The walkway 130 comprises a plastic material, for example PVC. The walkway 130 allows a user to walk along the sides of the connected photovoltaic floatation devices 10. This allows for easy access to the devices 10 when adjustments need to be made or the floatation element 12 needs to be re-inflated or inserted with a new foam insert. For example, a user can use the walkway 130 to access the tops of the photovoltaic floatation devices 10 in order to remove a defective PV laminate panel 14 and replace said panel 14 with a new working panel 14.

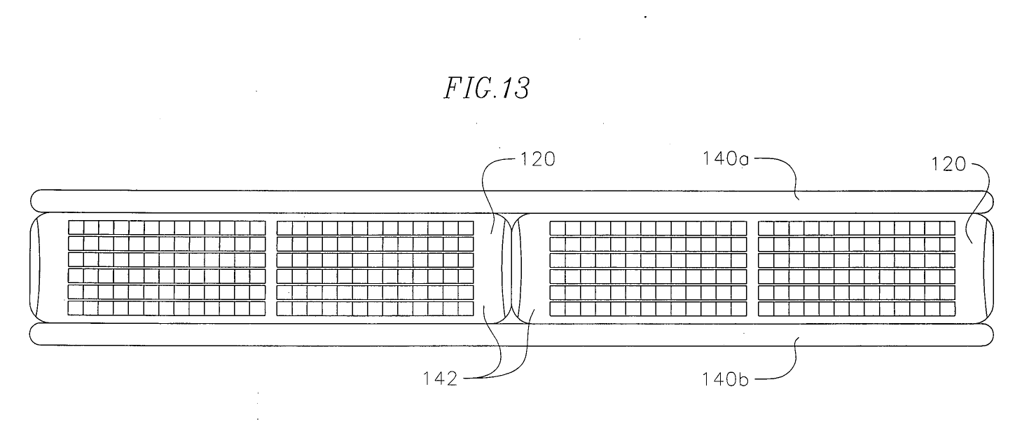

Referring to FIG. 13, in another embodiment, two main body pontoons 120 are attached at their ends. The two main body pontoons 120 are permanently heat welded together. Alternatively, the two main body pontoons 120 may be attached with grommet tabs 28 and carabiner connectors 29.

Two stabilizing pontoons 140a and 140b, each of which are as long as the combined length of the connected main body pontoons 142, are then attached along the sides of the connected main body pontoons 142. The stabilizing pontoons 140a and 140b are permanently affixed with a heat weld to the connected main body pontoons 142. Alternatively, The stabilizing pontoons 140a and 140b are attached to the sides of the connected main body pontoons 142 with grommet tabs and carabiner connectors.

In this configuration, the connected main body pontoons 142 are kept rigid and straight with tension caused by the stabilzing pontoon elements 140. This configuration may be particularly useful in rough waters where reinforcement of the connection between the connected main body pontoons 142 is advantageous.

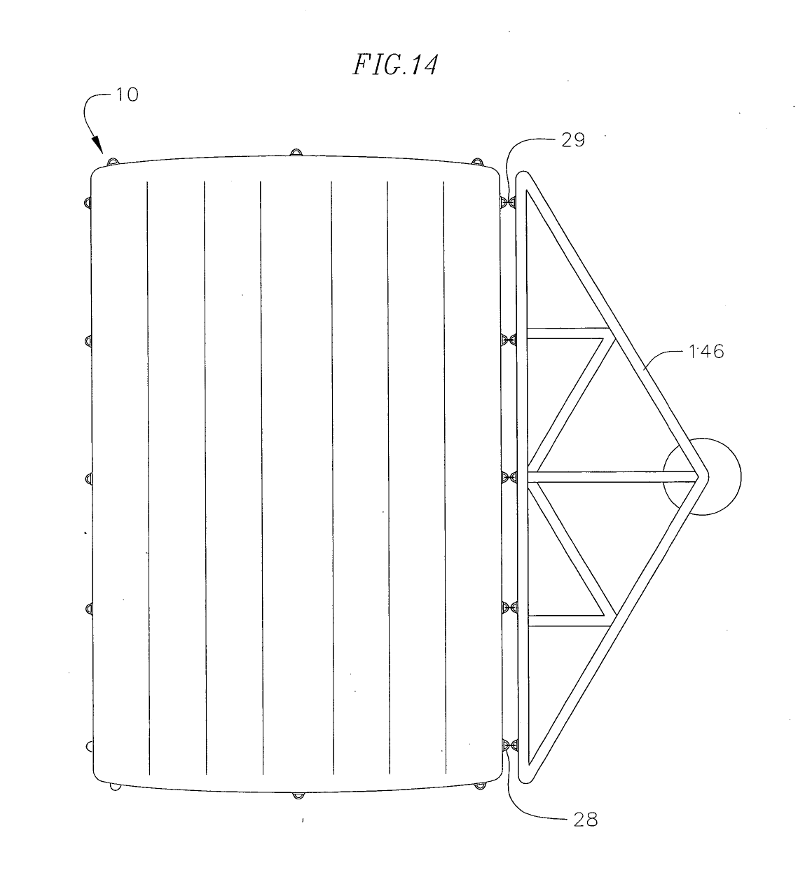

Referring to FIG. 14, in another embodiment, the photovoltaic floatation device 10 can be attached to one or more floating scaffolds 146. The floating scaffolds 146 are attached along the perimeter of the device with fasteners such as grommet 28 tabs in combination with carabiner connectors 29. The one or more floating scaffolds 146 give shape and rigidity to the device 10.

The PV laminate panel 14 can be attached to the floatation element 12 before or after the floatation element 12 is inflated. When assembling the photovoltaic floatation device 10, the floatation element 12 may be rolled up into a cylinder shape, with the PV laminate panel 14 already attached, with an air passage 26 exposed.

The device may be both inflated and deployed simultaneously. While in its rolled state, the device 10 may be placed in the water, an air supply may be connected to the exposed inflation device 26 and the cavity formed by the skin 16 inflated with air. As the cavity formed by the skin 16 is inflated, the floatation element 12 will begin to unroll as it expands with air. Thus, the floatation element 12 can be unrolled and prepared for use simply by inflating it. Alternatively, the user can manually unroll the floatation element 12 on the shore, inflate it and then deploy the device into the water from the shore.

To deploy one or more photovoltaic floatation devices 10, a user can inflate the cavity formed by the skin 16 of the floatation element 12 after the device 10 is placed into the water. A single device 10 is placed into the water, inflated, and then connected mechanically to a second device 10 with grommet tabs 28 and carabiner connectors 29. This process is repeated where a second device 10 is then mechanically connected to the already deployed device 10, the second device 10 is then inflated and finally deployed. The user can repeat these steps until the desired number of devices 10 have been deployed. The user may deploy the devices from the shore or from a floating body in the water. Electrical cables are then ran from the devices 10 to one or more combiner boxes, which combine the current produced by two or more devices 10.

In another embodiment, the user inflates the number of devices 10 the user desires to deploy. The user then mechanically, or magnetically, connects the assembled devices 10 together. Finally, the user deploys the assembled and connected devices 10 into the water as a batch. This method may be more feasible in instances where the user has a lot of space to spread out the fully assembled devices 10 on the shore before deployment.

In the embodiment of the device with a foam insert, the bottom portion of the floatation element is inflated and then the foam insert is inserted into the top of the floatation element. Once the floatation element is fully assembled, the device is deployed into the water. In the case of multiple devices, one device is placed into the water and then mechanically, or magnetically, connected to a second device, which is then placed into the water. This step is repeated until the specified number of devices have been placed into the water.

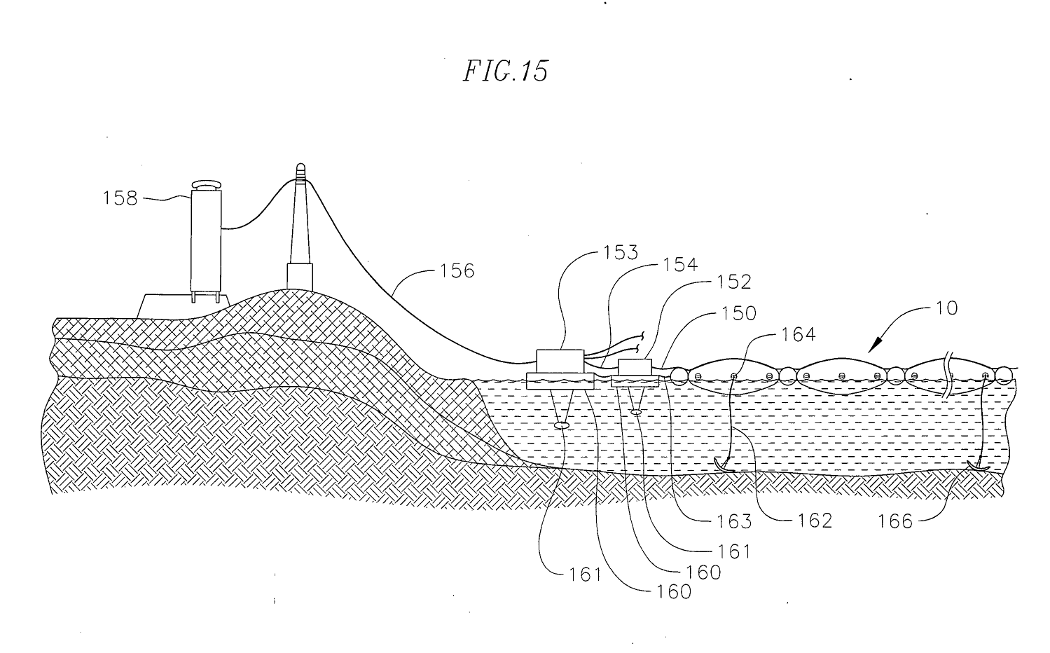

Referring to FIG. 15, while in use the photovoltaic floatation device 10 is located on a body of water. One or more electrical cables 150 are used to electrically connect the photovoltaic modules of the multiple devices 10 to one or more combiner boxes 152. The combiner boxes 152 are then connected with electrical cables 154 to combiner-combiner boxes 153, which combine the current from the multiple combiner boxes 152. The current from the combiner-combiner boxes 153 is then transferred through an electrical cable 156 to an inverter 158 that is located in an area accessible to the photovoltaic devices 10.

The combiner boxes 152 and the combiner-combiner boxes 153 rest on floats 160 in the body of water. The floats 160 are also connected to counterbalance weights 161 to prevent the floats 160 from flipping over in rough water. Furthermore, the floats are connected to the one or more photovoltaic floatation devices with a rope 163 to prevent the floats 160 from being carried away from the currents. Alternatively, the combiner boxes 152 and the combiner-combiner boxes 153 rest along the interface, for example on a walkway, where two or more devices 10 are attached.

The photovoltaic floatation device 10 is placed in a body of water, where it floats on the surface while exposing the photovoltaic modules 60 to sunlight. The photovoltaic floatation device 10 is secured to a desired location within the body of water with anchor cables 162, which are attached to an end 164 of the photovoltaic floatation device 10, with for example a carabiner connector and grommet tabs. The anchor cables 162 are then secured to an anchor 166, which has been sunk to the bottom of the body of water.

The length of the anchor cables 162 is varied depending on the freedom of movement the user desires of the photovoltaic floatation devices 10 as well as the depth of the body of water. Furthermore, the strength of the anchor cables 162 can be varied depending on the severity of the potential surge forces present at the surface of the body of water.

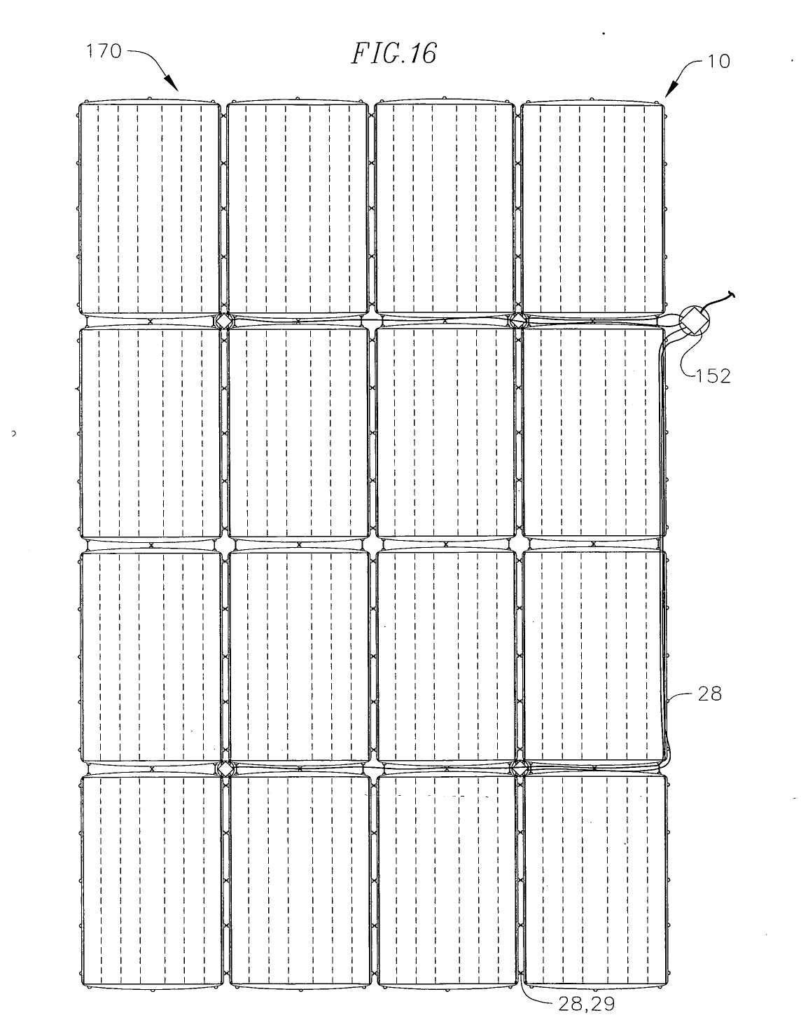

Referring to FIG. 16, multiple photovoltaic floatation devices 10 are mechanically, or magnetically, connected to form a photovoltaic floatation device grid 170. In this configuration, a plurality of photovoltaic floatation devices 10 are arranged both side-by-side and end-to-end so that a grid-like organization results. Multiple devices 10 are electrically connected to combiner boxes 152, which receive current from the devices 10 and transfer the current to either a combiner-combiner box 153 or an inverter 158. Furthermore, the plurality of photovoltaic flotation devices 10 are mechanically connected with grommet tabs 28 and carabiner connectors 29. Photovoltaic modules can also be electrically connected as described in U.S. Publication Nos. 2004/01440434 and 2005/0072456.

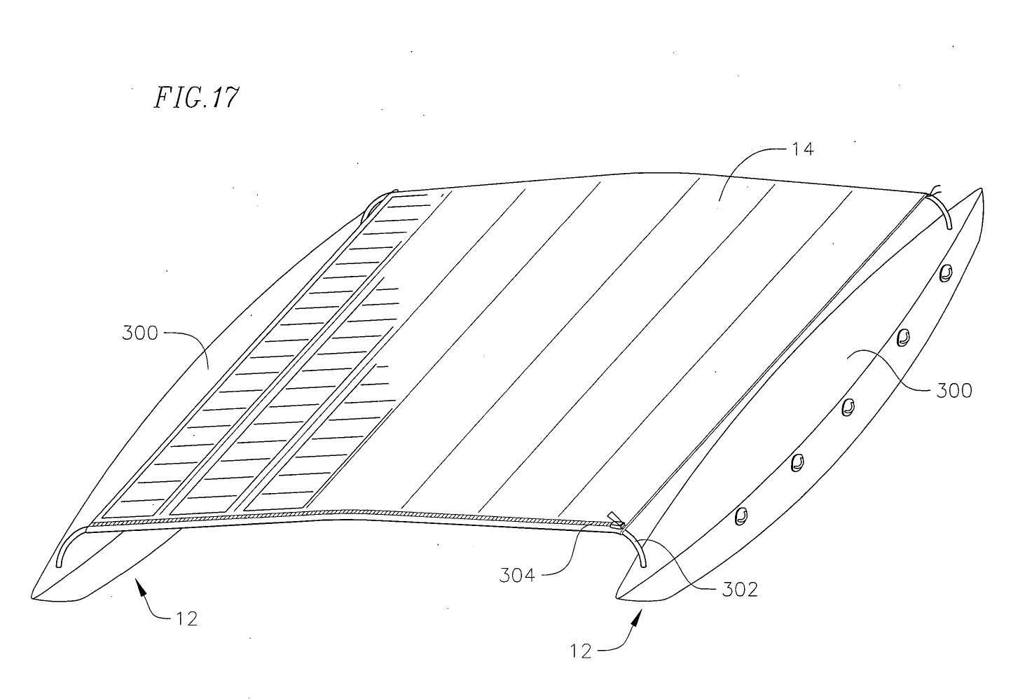

Referring to FIG. 17, in another embodiment the PV laminate panel 14 is removably attached to a catamaran style floatation element 12. The floatation element 12 includes two fiberglass floats 300, which are shaped like long, skinny ovals, similar to the shape of a canoe. Attached at each end of the floats 300 are sloping bars 302, which attach two parallel floats 300 at both ends of the floats 300. The sloping bars 302 are attached to the floats with bolts. However, one skilled in the art would appreciate that the sloping bars 302, or other suitable support elements, can be attached to the floats 300 in any way that would adequately secure the bars 302 to floats 300 and withstand the current forces in the body of water.

Heat welded to the sloping bars 302 are a set of teeth, which along with teeth that are attached at the ends of the PV laminate panel 14 form a zipper mechanism 304. The PV laminate panel 14 is stretched between the two parallel sloping bars 302 and attached with the zipper mechanism 304 to both bars 302. Once fully attached the PV laminate panel assumes the sloped shape of the sloping bars 302.

The foregoing description of embodiments of the present invention have been presented for purposes of illustration and description. It is not intended to be exhaustive or to limit the invention to the precise forms disclosed. Many modifications and variations are possible in light of the above teaching. It is intended that the scope of the invention be limited not by this detailed description, but rather by the claims appended hereto.

What is claimed is:

1. A photovoltaic floatation device comprising:
a photovoltaic laminate panel; and
a floatation element, wherein the photovoltaic laminate panel is removably attached to the floatation element.

2. The photovoltaic floatation device of claim 1, wherein the top of the floatation element has a slope for shedding water from the device.

3. The photovoltaic floatation device of claim 2, wherein the slope is not greater than 5 degrees.

4. The photovoltaic floatation device of claim 1, wherein one or more electrical leads connect one or more electrical connectors to the one or more photovoltaic cells.

5. The photovoltaic floatation device of claim 1, wherein the floatation element comprises one or more stabilizing pontoons removably attached to a main body pontoon.

6. The photovoltaic floatation device of claim 1, wherein the photovoltaic laminate panel is made of a flexible material.

7. The photovoltaic floatation device of claim 1, wherein one or more fasteners, configured to removably attach more than one photovoltaic floatation device, are attached to the outer perimeter of the floatation element.

8. The photovoltaic floatation device of claim 1, wherein the floatation element comprises one or more inflatable air bladders.

9. The photovoltaic floatation device of claim 8, wherein the one or more inflatable air bladders are in fluid communication with one another.

10. The photovoltaic floatation device of claim 8, wherein the one or more inflatable air bladders are not in fluid communication with one another.

11. The photovoltaic floatation device of claim 8, wherein an inflation device extends from the one or more air bladders.

12. The photovoltaic floatation device of claim 8, wherein the floatation element comprises one or more replaceable foam material inserts.

13. A system for generating electricity comprising:
a plurality of photovoltaic floatation devices mechanically connected to each other with one or more fasteners and electrically connected to one or more combiner boxes, each photovoltaic device comprising a PV laminate panel removably attached to a floatation element;
wherein the one or more combiner boxes are electrically connected to one or more inverters.

14. The system of claim 13, wherein one or more anchors are attached to the plurality of photovoltaic floatation devices with one or more anchor cables.

15. The system of claim 13, wherein one or more pylons support and guide one or more electrical cables from the one or more combiner boxes to the one or more inverters.

16. A photovoltaic floatation device comprising:
a photovoltaic laminate panel; and
a floatation element, wherein the photovoltaic laminate panel is attached to the floatation element and wherein the top of the floatation element has a slope for shedding water.

17. The photovoltaic floatation device of claim 16, wherein the top of the floatation element slopes downward towards an outer perimeter of the device.
